(19) United States
(12) Patent Application Publication
(10) Pub. No.: US 2026/0068533 A1
(43) Pub. Date: Mar. 5, 2026

(54) HAPTIC DEVICE AND VIBROTACTILE COMPONENT

(71) Applicant: Industrial Technology Research Institute, Hsinchu (TW)

(72) Inventors: Li-Wei Yao, Hsinchu County (TW); Heng-Chung Chang, Taichung City (TW); Chung-Wei Wang, New Taipei City (TW)

(73) Assignee: Industrial Technology Research Institute, Hsinchu (TW)

(21) Appl. No.: 19/313,877

(22) Filed: Aug. 29, 2025

Related U.S. Application Data
(60) Provisional application No. 63/688,880, filed on Aug. 30, 2024.

(30) Foreign Application Priority Data
Jun. 6, 2025 (TW) 114121231

(51) Int. Cl. H10N 30/88; G06F 3/01; G08B 6/00; H10N 30/20

(52) U.S. Cl. CPC H10N 30/883; G08B 6/00; H10N 30/2047; G06F 3/016

(57) ABSTRACT

A vibrotactile component includes a first electrode, a second electrode, a piezoelectric layer, a support layer, a vibration layer, and a counterweight. The piezoelectric layer is disposed between the first electrode and the second electrode. The support layer is disposed on the first electrode. A gap is positioned between two opposite portions of the support layer. The vibration layer is disposed on the support layer and is spaced from the first electrode by the support layer and the gap. The counterweight is disposed on the vibration layer. The vibration layer is disposed between the air gap and the counterweight.

### CROSS-REFERENCE TO RELATED APPLICATION(s)

This application claims priority to and the benefit of U.S. Provisional Application No. 63/688,880, filed on Aug. 30, 2024, and Taiwan Application No. 114121231, filed on Jun. 6, 2025. The above-mentioned applications are incorporated by reference.

### TECHNICAL FIELD

The technical field is related to a haptic device.

### BACKGROUND

Although virtual reality (VR) and augmented reality (AR) have become increasingly mature in terms of visual and auditory experiences, haptics related to this field (including vibration, temperature, force feedback, surface texture perception, etc.) still faces technical challenges, making it difficult to achieve realistic tactile sensations. Current haptic devices used in VR and AR are generally bulky, uncomfortable, and limited in function. Current rigid actuators are limited in size and frequency. When providing vibration feedback, the actuators reduce the realism of the tactile sensation and the feedback response time is not fast enough, affecting the user experience. Current flexible vibration elements are limited by the inherent piezoelectric physical properties of polymer materials and have to operate under high voltage to provide significant vibration feedback. In addition, current hydraulic deformation haptic devices require a fluid reservoir to operate, but the reservoir is unable to satisfy the requirement for thinness (less than 1 mm), and the reservoir is not flexible and is unable conform to the curvature of a finger. Therefore, it is desirable to develop lighter, more comfortable, and functionally diverse haptic devices.

### SUMMARY

An embodiment may be related to a haptic device. The haptic device may include a first electrode, a second electrode, a piezoelectric layer, a support layer, a vibration layer, a counterweight, an electrostatic friction component, and a deformation component. The piezoelectric layer may be disposed between the first electrode and the second electrode. The support layer may be disposed on the first electrode. A gap may be positioned between two portions of the support layer. The vibration layer may be disposed on the support layer and may be spaced from the first electrode by the support layer and the gap. The counterweight may be disposed on the vibration layer. The vibration layer may be disposed between the gap and the counterweight. The deformation component may be disposed between the second electrode and the electrostatic friction component.

An embodiment may be related to a vibrotactile component. The vibrotactile component may include a first electrode, a second electrode, a piezoelectric layer, a support layer, a vibration layer, and a counterweight. The piezoelectric layer may be disposed between the first electrode and the second electrode. The support layer may be disposed on the first electrode. A gap may be positioned between two opposite portions of the support layer. The vibration layer may be disposed on the support layer and may be spaced from the first electrode by the support layer and the gap. The counterweight may be disposed on the vibration layer. The vibration layer may be disposed between the air gap and the counterweight.

An embodiment may be related to a haptic device. The haptic device may include an above-described vibrotactile component, a carrier, and a control unit, The control unit may be disposed on the carrier and may be electrically connected to the vibrotactile component.

### BRIEF DESCRIPTION OF THE DRAWINGS

FIG. 1A, FIG. 1B and FIG. 1C show schematic cross-sectional views of a haptic device according to an embodiment.

FIG. 2 shows schematic cross-sectional views of a haptic device according to an embodiment.

FIG. 3 shows schematic cross-sectional views of a haptic device according to an embodiment.

FIG. 4 shows schematic cross-sectional views of the deformation component, the vibrotactile component, and the electrostatic friction component of a haptic device according to an embodiment.

FIG. 5A, FIG. 5B, FIG. 5C, FIG. 5D, FIG. 5E, FIG. 5F, FIG. 5G, FIG. 5H, FIG. 5I, FIG. 5J, FIG. 5K, FIG. 5L, FIG. 5M, FIG. 5N, FIG. 5O, FIG. 5P, and 5Q are schematic cross-sectional views of structures formed in a manufacturing process of a haptic device according to one or more embodiments.

FIGS. 6A and 6B are schematic top views of one or more structures including a photosensitive material according to an embodiment.

FIG. 7 is a schematic top view of a conductive layer of a deformation component according to an embodiment.

FIG. 8A is a schematic top view illustrating a structure before a dielectric fluid is filled according to an embodiment.

FIG. 8B is a schematic top view illustrating a structure after a dielectric fluid is filled according to an embodiment.

FIG. 9 is a schematic top view illustrating a structure after a dielectric fluid is filled in an insulating layer according to an embodiment.

FIG. 10 shows a schematic cross-sectional view of a haptic device and a schematic top view schematic diagram of a deformation component according to one or more embodiments.

FIG. 11 is a schematic cross-sectional view of a haptic device according to an embodiment.

FIG. 12 is a schematic cross-sectional view of a haptic device according to an embodiment.

FIG. 13 is a schematic cross-sectional view of a vibrotactile component according to an embodiment.

FIG. 14 is a schematic perspective view illustrating a counterweight, a vibration layer, and a support layer of a vibrotactile component according to an embodiment.

FIG. 15 is a schematic cross-sectional view of a vibrotactile component according to an embodiment.

FIG. 16A, FIG. 16B, and FIG. 16C are schematic diagrams illustrating different flexible piezoelectric layer designs of one or more vibrotactile components according to one or more embodiments.

Each of FIG. 17A, FIG. 17B, FIG. 17C, FIG. 17D, FIG. 18A, FIG. 18B, FIG. 18C, FIG. 18D, FIG. 19A, FIG. 19B, FIG. 19C, and FIG. 19D is a schematic top view illustrating a counterweight, a vibration layer, and a support layer of a vibrotactile component according to an embodiment.

FIG. 20 is a schematic cross-sectional view of a vibrotactile component according to an embodiment.

FIG. 21 shows schematic diagrams illustrating a vibrotactile component and a knob including the vibrotactile component according to an embodiment.

FIG. 22 is a schematic diagram illustrating a piece of fabric including a vibrotactile component according to an embodiment.

FIG. 23 is a schematic diagram illustrating a ring-shaped device (for example, a ring) including a vibrotactile component according to an embodiment.

FIG. 24 shows schematic diagrams illustrating a vibrotactile component and a frame of (smart) glasses including the vibrotactile component according to an embodiment.

### DETAILED DESCRIPTION OF DISCLOSED EMBODIMENTS

Although the terms “first,” “second,” etc. may be used to describe various elements, these elements should not be limited by these terms. These terms may be used to distinguish one element from another element. A first element may be termed a second element without departing from teachings of the disclosure. The description of an element as a “first” element may not require or imply the presence of a second element or other elements. The terms “first,” “second,” etc. may be used to differentiate different categories or sets of elements. For conciseness, the terms “first,” “second,” etc. may represent “first-category (or first-set),” “second-category (or second-set),” etc., respectively. The term “on” may mean “directly on” or “indirectly on.” The term “connect” may mean “directly connect” or “indirectly connect.” The term “connect” may mean “mechanically connect” and/or “electrically connect.” The term “insulate” may mean “electrically insulate” or “electrically isolate.” The term “conductive” may mean “electrically conductive.” The term “overlap” may be equivalent to “be overlapped by.” The term “top view” may mean “plan view.” When a first element and a second element are respectively disposed on two opposite sides of a third element, the third element may be disposed between the first element and the second element. The term “define” may mean “form.” The term “pattern” may mean “member.” The term “contact” may mean “directly contact.” The term “drive” may mean “control” or “operate.” The term “is” may mean “may be.” The term “are” may mean “may be.” The term “includes” may mean “may include.” A list of materials may mean at least one of the listed materials. An expression of a first value to a second value may mean in a range of the first value to the second value. An expression of between a first value and a second value may mean in a range of the first value to the second value.

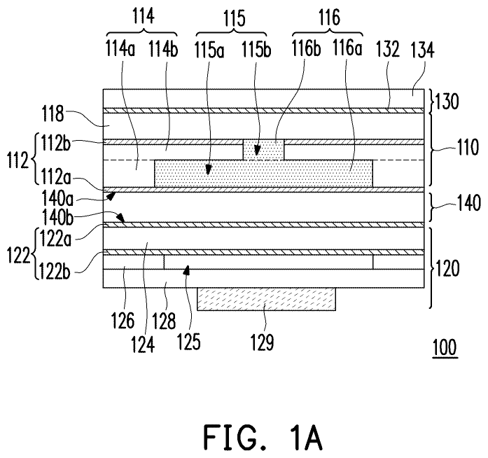

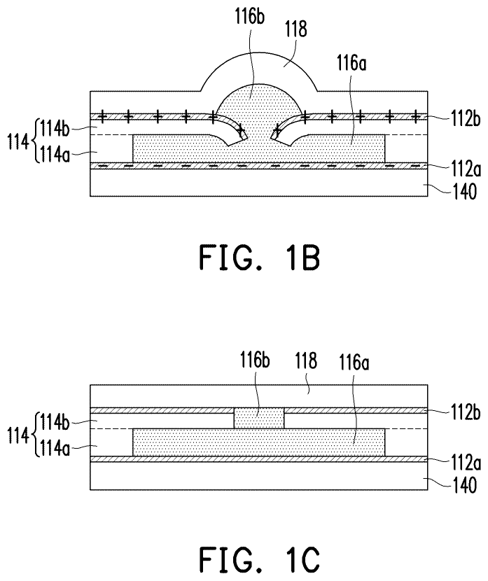

FIG. 1A, FIG. 1B and FIG. 1C show schematic cross-sectional views of a haptic device according to an embodiment.

Referring to FIG. 1A, FIG. 1B and FIG. 1C, a haptic device 100 includes a deformation component 110, a vibrotactile component 120, and an electrostatic friction component 130, wherein the vibrotactile component 120 and the electrostatic friction component 130 are respectively disposed on two opposite sides of the deformation component 110, i.e., the deformation component 110 is positioned between the vibrotactile component 120 and the electrostatic friction component 130. For example, the vibrotactile component 120 is disposed below the deformation component 110, and the electrostatic friction component 130 is disposed above the deformation component 110. The deformation component 110, the vibrotactile component 120, and the electrostatic friction component 130 are all flexible components in the form of thin films. Therefore, the haptic device 100 may meet requirements of flexibility, lightness, and/or comfort. The haptic device 100 integrating the deformation component 110, the vibrotactile component 120, and the electrostatic friction component 130 may provide various types of haptics, such as vibration, force feedback, and/or surface texture perception.

The haptic device 100 may further include a flexible substrate 140, wherein the deformation component 110 and the vibrotactile component 120 share the flexible substrate 140, and the deformation component 110 and the vibrotactile component 120 are respectively located on two opposite sides of the flexible substrate 140. For example, the vibrotactile component 120 is disposed below the flexible substrate 140, and the deformation component 110 and the electrostatic friction component 130 are disposed above the flexible substrate 140. The deformation component 110 includes a first electrode pair 112, an insulating layer 114, a dielectric fluid 116, and a deformation layer 118. The first electrode pair 112 is disposed on a first surface 140a of the flexible substrate 140, and the first electrode pair 112 includes a bottom electrode 112a and a top electrode 112b that are separated from each other. The insulating layer 114 is disposed between the bottom electrode 112a and the top electrode 112b of the first electrode pair 112 and may define a microfluidic chamber 115. The dielectric fluid 116 is embedded in the insulating layer 114, and the dielectric fluid 116 is located between the bottom electrode 112a and the top electrode 112b and located in the microfluidic chamber 115. The deformation layer 118 is disposed on the top electrode 112b and on the dielectric fluid 116, wherein the dielectric fluid 116 contacts the top electrode 112b of the first electrode pair 112, the insulating layer 114, and the deformation layer 118.

As shown in FIG. 1A, FIG. 1B and FIG. 1C, the insulating layer 114 includes a first insulating portion 114a and a second insulating portion 114b, wherein the first insulating portion 114a contacts the bottom electrode 112a. The first insulating portion 114a defines a first microfluidic chamber region 115a of the microfluidic chamber 115. The second insulating portion 114b contacts the top electrode 112b. The second insulating portion 114b is located between the first insulating portion 114a and the top electrode 112b, and the second insulating portion 114b defines a second microfluidic chamber region 115b of the microfluidic chamber 115. The first microfluidic chamber region 115a communicates with (i.e., is directly connected to) the second microfluidic chamber region 115b. The dielectric fluid 116 includes a first portion 116a contained in the first microfluidic chamber region 115a (and directly contacting two opposite sections of the first insulating portion 114a) and a second portion 116b contained in the second microfluidic chamber region 115b (and directly contacting two opposite sections of the second insulating portion 114b). A maximum height of the first microfluidic chamber region 115a is between 10 micrometers and 200 micrometers, and a maximum width of the first microfluidic chamber region 115a is between 50 micrometers and 2000 micrometers.

A material of the first electrode pair 112 includes a metal, such as copper (Cu), titanium (Ti), molybdenum (Mo), gold (Au), silver (Ag), aluminum (Al), an alloy of some of the above materials, or at least one of other similar metals. A material of the insulating layer 114 includes a photo-curable resin, such as at least one of polydimethylsiloxane (PDMS), polyimide (PI), polyethylene terephthalate (PET), polyvinyl chloride (PVC), etc. A viscosity coefficient of the dielectric fluid 116 is between 0.001 Pa and 10 Pa. For example, a material of the dielectric fluid 116 includes at least one of air, water, silicone oil, and tar. A material of the deformation layer 118 includes at least one of thermoplastic polyurethane (TPU), polyurethane (PU), polydimethylsiloxane (PDMS), etc. A material of the flexible substrate 140 includes at least one of polydimethylsiloxane (PDMS), polyimide (PI), polyethylene terephthalate (PET), polyvinyl chloride (PVC), etc.

As shown in FIG. 1B, when the deformation component 110 in the haptic device 100 is in an on state, a cross-voltage (for example, 100 volts to 350 volts) may be applied between the bottom electrode 112a and the top electrode 112b, so that a desired deformation amount is generated in the deformation layer 118 in the deformation component 110. The cross-voltage applied between the bottom electrode 112a and the top electrode 112b causes the dielectric fluid 116 to be compressed, and the compressed dielectric fluid 116 pushes the deformation layer 118 to bulge upward. As shown in FIG. 1B, when the deformation component 110 in the haptic device 100 is in an on state, a portion of the deformation layer 118 located above the second microfluidic chamber region 115b generates a corresponding deformation amount according to the cross-voltage applied between the bottom electrode 112a and the top electrode 112b. As the cross-voltage applied between the bottom electrode 112a and the top electrode 112b increases, the deformation amount (i.e., degree of bulging) of the deformation layer 118 in the deformation component 110 increases.

As shown in FIG. 1A and FIG. 1C, when the deformation component 110 in the haptic device 100 is in an off state, a volume ratio of the first microfluidic chamber region 115a to the second microfluidic chamber region 115b is between 2 and 100. For example, when the deformation component 110 in the haptic device 100 is in an off state, the volume ratio of the first microfluidic chamber region 115a to the second microfluidic chamber region 115b is approximately 38. Therefore, when the deformation component 110 in the haptic device 100 is in an off state, a volume ratio of the first portion 116a contained in the first microfluidic chamber region 115a to the second portion 116b contained in the second microfluidic chamber region 115b is between 2 and 100. For example, when the deformation component 110 in the haptic device 100 is in an off state, the volume ratio of the first portion 116a contained in the first microfluidic chamber region 115a to the second portion 116b contained in the second microfluidic chamber region 115b is approximately 38.

The vibrotactile component 120 includes a second electrode pair 122, a flexible piezoelectric layer 124, a support layer 126, a vibration layer 128, and a counterweight 129. The second electrode pair 122 is disposed on a second surface 140b of the flexible substrate 140. The second surface 140b is opposite the first surface 140a. The second electrode pair 122 includes a first electrode 122b and a second electrode 122a that are separated from each other by the flexible piezoelectric layer 124. The flexible piezoelectric layer 124 is disposed between the second electrode 122a and the first electrode 122b. The support layer 126 is disposed on the second electrode pair 122 to define a gap, e.g., an air gap 125, positioned between two opposite portions of the support layer 126. The support layer 126 and the flexible substrate 140 are respectively located on two opposite sides of the second electrode pair 122. The vibration layer 128 is disposed on the support layer 126, wherein the vibration layer 128 and the second electrode pair 122 are spaced from each other by the air gap 125. The counterweight 129 is disposed on the vibration layer 128. A material of the second electrode pair 122 includes a metal, such as copper (Cu), titanium (Ti), molybdenum (Mo), gold (Au), silver (Ag), aluminum (Al), an alloy of the above materials, or other similar metals. In some embodiments, a material of the second electrode pair 122 includes a conductive polymer. The conductive polymer may include an organic polymer and conductive particles mixed in the organic polymer, wherein the organic polymer includes, for example, polyimide, polyester, polyolefins, polyether polyol, or other suitable materials, and the conductive particles include, for example, silver nanowires or carbon nanotubes, or other suitable materials. In some embodiments, the second electrode pair 122 includes a metal and a conductive polymer. The conductive polymer may be formed on a surface of the metal to form a multilayer conductive structure, wherein the metal includes, for example, copper (Cu), titanium (Ti), molybdenum (Mo), gold (Au), silver (Ag), aluminum (Al), an alloy of the above materials, or other similar metals, and the conductive polymer may include an organic polymer and conductive particles mixed in the organic polymer, wherein the organic polymer includes, for example, polyimide, polyester, polyolefins, polyether polyol, or other suitable materials, and the conductive particles include, for example, silver nanowires or carbon nanotubes, or other suitable materials.

The electrostatic friction component 130 includes an electrode 132 and an electrostatic friction layer 134, wherein the electrode 132 is disposed on the deformation layer 118 of the deformation component 110, and the electrostatic friction layer 134 is disposed on the electrode 132. For example, a material of the electrode 132 includes a metal, such as copper (Cu), titanium (Ti), molybdenum (Mo), gold (Au), silver (Ag), aluminum (Al), an alloy of the above materials, or other similar metals. A material of the electrostatic friction layer 134 includes a photo-curable resin, such as polydimethylsiloxane (PDMS), polyvinylidene fluoride (PVDF), polyimide (PI), polyethylene terephthalate (PET), polyvinyl chloride (PVC), silicon dioxide (SiO₂), silicon nitride (Si₃N₄), and other organic or inorganic high dielectric materials.

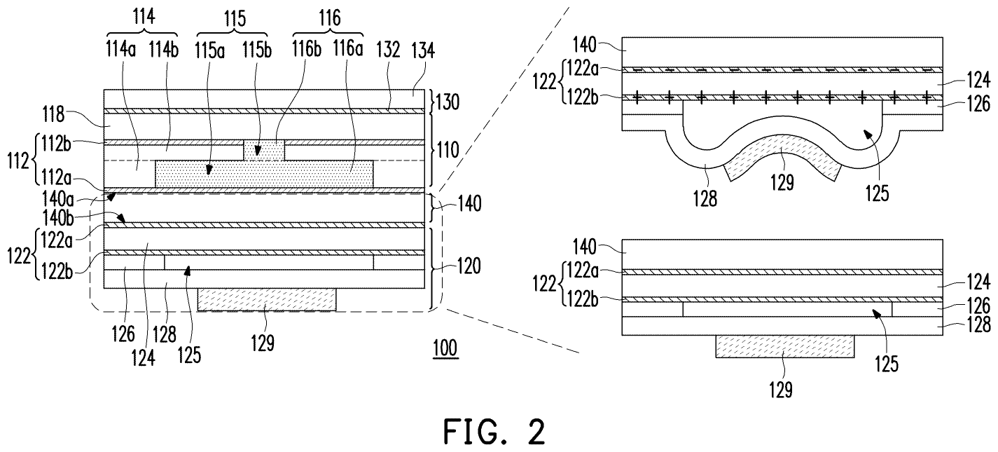

FIG. 2 is a schematic cross-sectional view of the haptic device according to an embodiment.

Referring to FIG. 2, when the vibrotactile component 120 in the haptic device 100 is in an on state, a cross-voltage may be applied between the second electrode 122a and the first electrode 122b, so that the vibration layer 128 and the counterweight 129 in the vibrotactile component 120 generate vibration of a desired resonance frequency, thereby simulating the tactile sensation of a rough surface texture and a fine surface texture. As shown in the upper right part of FIG. 2, when the vibrotactile component 120 in the haptic device 100 is in an on state, the vibration layer 128 and the counterweight 129 generate corresponding vibration according to the cross-voltage applied between the second electrode 122a and the first electrode 122b. As shown in the lower right part of FIG. 2, when the vibrotactile component 120 in the haptic device 100 is in an off state, the vibration layer 128 and the counterweight 129 in the vibrotactile component 120 are in a static state.

The vibrotactile component 120 are further described with reference to FIGS. 13 to 20.

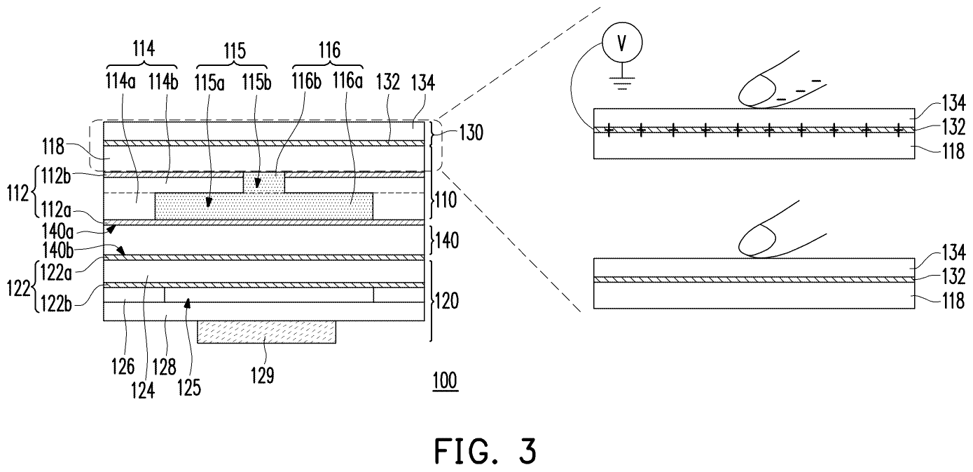

FIG. 3 is a schematic cross-sectional view of the haptic device according to an embodiment.

Referring to FIG. 3, when the electrostatic friction component 130 in the haptic device 100 is in an on state, a voltage may be applied to the electrode 132 to provide charges to the electrode 132. When a user touches the electrostatic friction component 130 in the on state, the user feels the friction force of the electrostatic friction layer 134, and the friction force comes from the electrostatic friction force generated by electrostatic attraction.

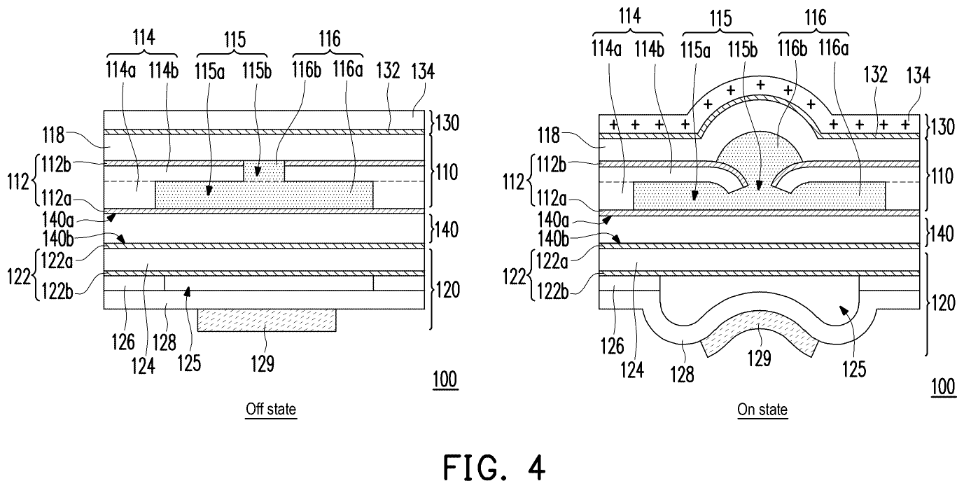

FIG. 4 is a schematic cross-sectional view of the deformation component, the vibrotactile component, and the electrostatic friction component of the haptic device according to an embodiment.

Referring to FIG. 4, when the deformation component 110, the vibrotactile component 120, and the electrostatic friction component 130 in the haptic device 100 are all in an on state, the operating mechanism of the deformation component 110 is as shown in FIG. 1B, FIG. 1C and the related description, the operating mechanism of the vibrotactile component 120 is as shown in FIG. 2 and the related description, and the operating mechanism of the electrostatic friction component 130 is as shown in FIG. 3 and the related description. As shown in the right half of FIG. 4, when the deformation component 110 is in an on state, a portion of the deformation layer 118 located above the second microfluidic chamber region 115b generates a corresponding deformation (for example, bulging) amount according to the cross-voltage applied between the bottom electrode 112a and the top electrode 112b, and the deformation component 110 drives the electrostatic friction component 130 to deform (for example, bulge) together. When the vibrotactile component 120 is in an on state, the vibration layer 128 and the counterweight 129 generate corresponding vibration according to the cross-voltage applied between the second electrode 122a and the first electrode 122b. When the electrostatic friction component 130 is in an on state, the voltage applied to the electrode 132 may provide charges to the electrode 132, so that when the user touches the electrostatic friction layer 134, the user may not only feel, by tactile sensation, the deformation (for example, bulging) of the deformation component 110 and the electrostatic friction component 130, but also feel the friction force provided by the electrostatic friction layer 134.

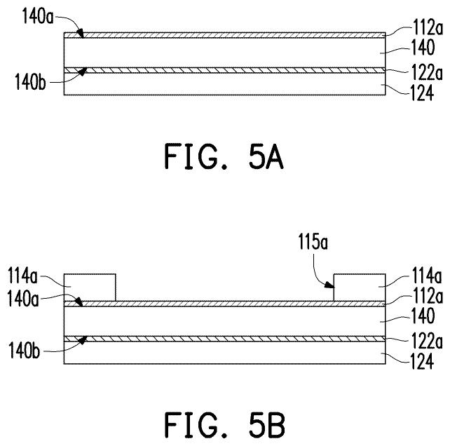

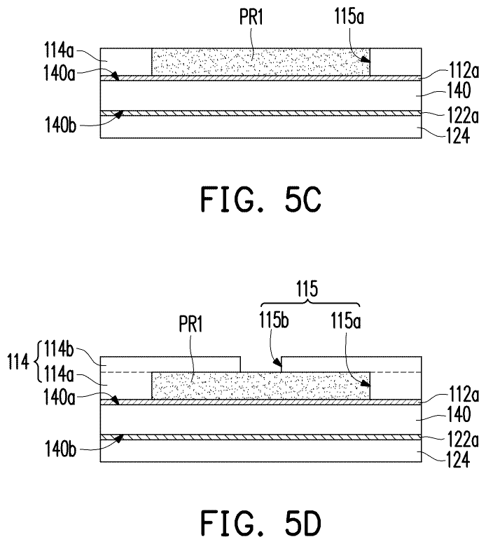

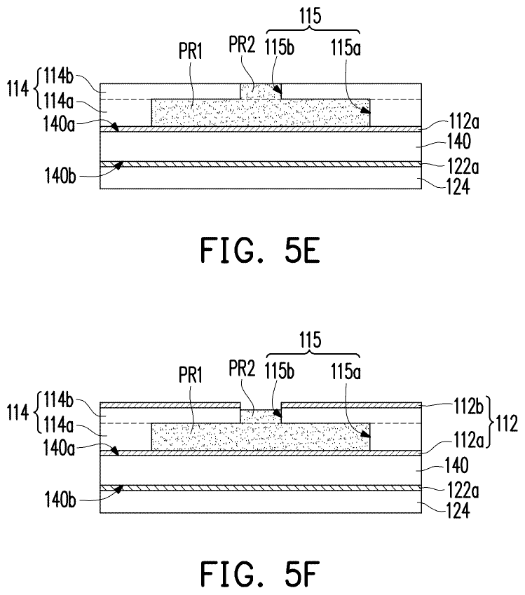

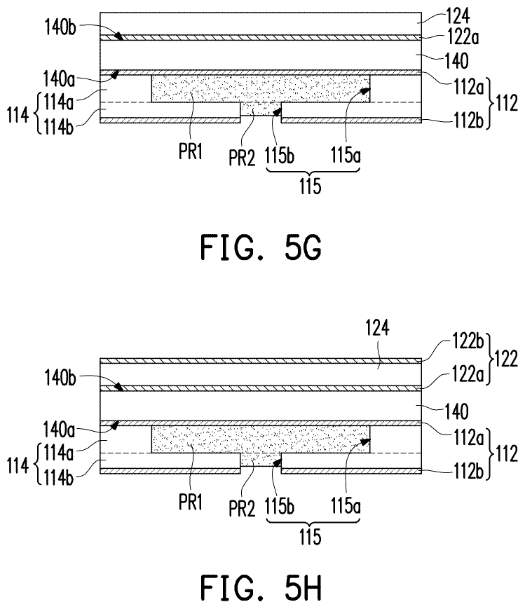

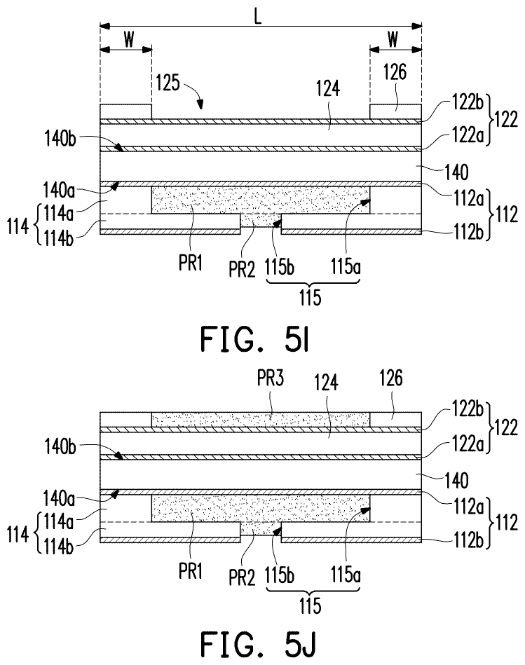

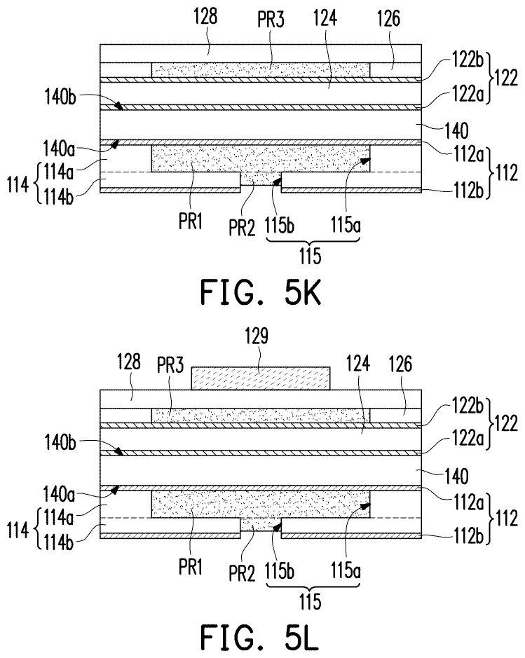

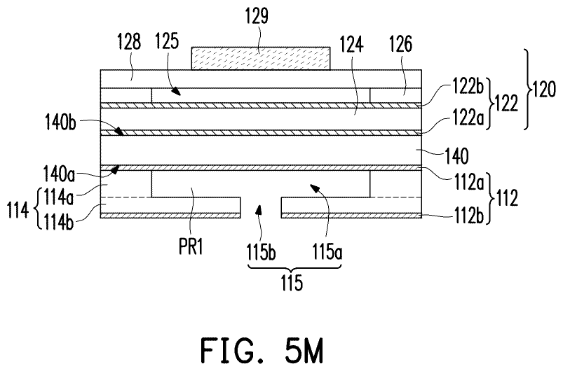

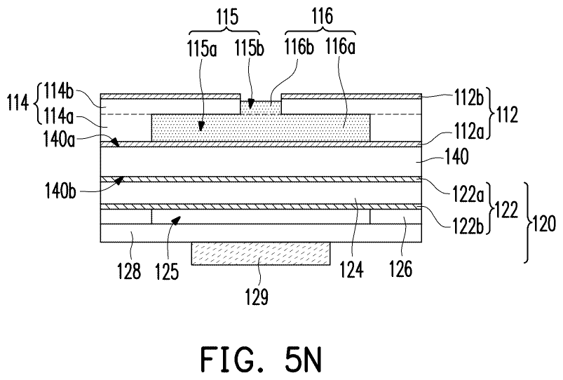

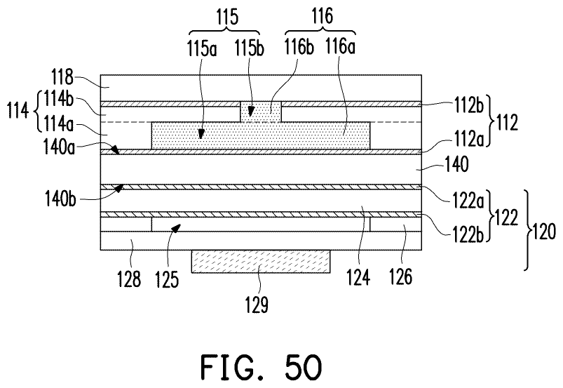

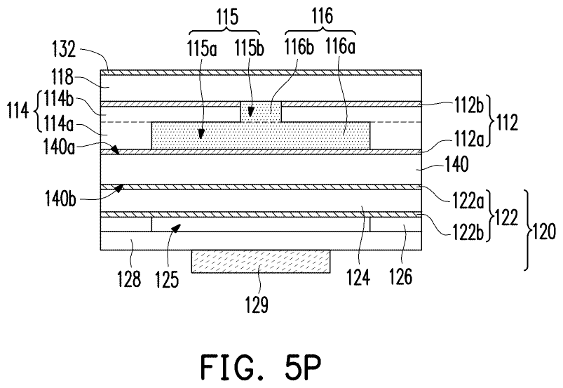

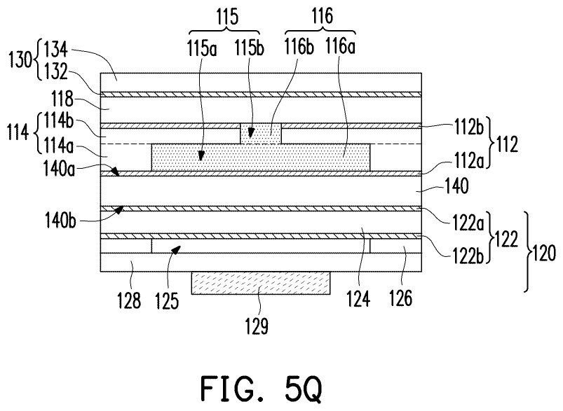

FIGS. 5A to 5Q are schematic cross-sectional views of structures formed in a manufacturing process of a haptic device according to an embodiment.

Referring to FIG. 5A, first, a flexible substrate 140 is provided. The flexible substrate 140 has a first surface 140a and a second surface 140b opposite the first surface 140a. A second electrode 122a and a flexible piezoelectric layer 124 are formed on the second surface 140b of the flexible substrate 140. A bottom electrode 112a is formed on the first surface 140a of the flexible substrate 140. The formation of the second electrode 122a and the flexible piezoelectric layer 124 may be performed before the formation of the bottom electrode 112a. In an embodiment, the formation of the second electrode 122a and the flexible piezoelectric layer 124 may be performed after the formation of the bottom electrode 112a. For example, the formation of the second electrode 122a and the flexible piezoelectric layer 124 may be performed after the step disclosed in FIG. 5G and before the step disclosed in FIG. 5H. In some embodiments in which the vibrotactile component 120 does not need to be manufactured, the formation of the second electrode 122a and the flexible piezoelectric layer 124 may be omitted.

A material of the bottom electrode 112a and the first electrode 122b includes a metal, such as copper (Cu), titanium (Ti), molybdenum (Mo), gold (Au), silver (Ag), aluminum (Al), an alloy of the above materials, or other similar metals. The bottom electrode 112a and the first electrode 122b may be made of the same or different materials. The bottom electrode 112a and the first electrode 122b may be manufactured on the flexible substrate 140 by screen printing.

A material of the flexible piezoelectric layer 124 includes an organic polymer, an inorganic ceramic thin film, a stacked structure formed by two soft and hard materials, or a mixed structure formed by two soft and hard materials. When the material of the flexible piezoelectric layer 124 is an inorganic ceramic thin film, a thickness of the inorganic ceramic thin film is between 100 nanometers and 3000 nanometers. The organic polymer may include at least one of polarized polyvinylidene fluoride (PVDF), poly (vinylidene fluoride-trifluoroethylene) (PVDF-TrFE), polyurethanes, polyamides, polypeptides, polyesters, etc. The inorganic ceramic thin films may include at least one of barium titanate (BaTiO₃, BTO), lead zirconate titanate (Pb(Zr,Ti)O₃, PZT), aluminum nitride (AlN), zinc oxide (ZnO), potassium sodium niobate ((K,N)NO₃, KNN), etc.

Referring to FIG. 5B, a first insulating portion 114a used to define the first microfluidic chamber region 115a is formed on the bottom electrode 112a. At this stage, a portion of the bottom electrode 112a is exposed by the first microfluidic chamber region 115a in the first insulating portion 114a. The first insulating portion 114a only covers a partial region of the bottom electrode 112a. A material of the first insulating portion 114a includes a photo-curable resin, such as polydimethylsiloxane (PDMS), polyimide (PI), polyethylene terephthalate (PET), polyvinyl chloride (PVC), etc. The first insulating portion 114a may be formed on the bottom electrode 112a by screen printing.

Referring to FIG. 5C, a first photoresist material PRI is formed on the bottom electrode 112a. The first photoresist material PRI is filled in the first microfluidic chamber region 115a. The first photoresist material PRI may be formed in the first microfluidic chamber region 115a by screen printing. As shown in FIG. 5C, a top surface of the first photoresist material PRI may be flush with a top surface of the first insulating portion 114a, so as to facilitate the subsequent process.

Referring to FIG. 5D, a second insulating portion 114b used to define the second microfluidic chamber region 115b is formed on the top surface of the first photoresist material PRI and the top surface of the first insulating portion 114a. At this stage, the second insulating portion 114b covers the top surface of the first insulating portion 114a and a partial region of the first photoresist material PR1. A material of the second insulating portion 114b includes a photo-curable resin, such as polydimethylsiloxane (PDMS), polyimide (PI), polyethylene terephthalate (PET), polyvinyl chloride (PVC), etc. The second insulating portion 114b may be formed on the first insulating portion 114a and the first photoresist material PRI by screen printing. As shown in FIG. 5D, the first insulating portion 114a and the second insulating portion 114b together form the insulating layer 114, and the first microfluidic chamber region 115a and the second microfluidic chamber region 115b together form the microfluidic chamber 115. The insulating layer 114 defines the microfluidic chamber 115.

Referring to FIG. 5E, a second photoresist material PR2 is formed on the first photoresist material PR1. The second photoresist material PR2 is filled in the second microfluidic chamber region 115b. The second photoresist material PR2 may be formed in the second microfluidic chamber region 115b by screen printing. As shown in FIG. 5E, a top surface of the second photoresist material PR2 may be flush with a top surface of the second insulating portion 114b, so as to facilitate the subsequent process.

Referring to FIG. 5F, a top electrode 112b is formed on a top surface of the second insulating portion 114b. A material of the top electrode 112b includes a metal, such as copper (Cu), titanium (Ti), molybdenum (Mo), gold (Au), silver (Ag), aluminum (Al), an alloy of the above materials, or other similar metals. The top electrode 112b may be formed on the top surface of the second insulating portion 114b by screen printing. At this stage, the second photoresist material PR2 is not covered by the top electrode 112b. The top electrode 112b only covers the top surface of the second insulating portion 114b and exposes the second photoresist material PR2.

Referring to FIGS. 5G and 5H, after the manufacturing of the top electrode 112b is completed, the structure in FIG. 5F is flipped, so that the flexible piezoelectric layer 124 is located above the flexible substrate 140. Next, as shown in FIG. 5H, a first electrode 122b is formed on a surface of the flexible piezoelectric layer 124. A material of the first electrode 122b includes a metal, such as copper (Cu), titanium (Ti), molybdenum (Mo), gold (Au), silver (Ag), aluminum (Al), an alloy of the above materials, or other similar metals. The first electrode 122b may be formed on the surface of the flexible piezoelectric layer 124 by screen printing.

Referring to FIG. 5I, a support layer 126 is formed on the first electrode 122b. A maximum width of the left or right portion of the support layer 126 is W, and a maximum width of the flexible piezoelectric layer 124 is L. A ratio of W to L is in a range of 1/10 to ½. A material of the support layer 126 includes a photo-curable resin, such as polydimethylsiloxane (PDMS), polyimide (PI), polyethylene terephthalate (PET), polyvinyl chloride (PVC), etc. The support layer 126 may be formed on the first electrode 122b by screen printing. In embodiments, a material of the support layer 126 may include other insulating materials with good support properties. The support layer 126 is used to define an air gap 125 so that a portion of the first electrode 122b below is exposed.

Referring to FIG. 5J, a third photoresist material PR3 is formed on the first electrode 122b. The third photoresist material PR3 is filled in the air gap 125. The third photoresist material PR3 may be formed in the air gap 125 by screen printing. As shown in FIG. 5J, a top surface of the third photoresist material PR3 may be flush with a top surface of the support layer 126, so as to facilitate the subsequent process.

Referring to FIG. 5K, a vibration layer 128 is formed on a top surface of the third photoresist material PR3 and a top surface of the support layer 126. A Young's module of the vibration layer 128 is in a range of 70 GPa to 210 GPa, and a thickness of the vibration layer 128 is greater than or equal to 3 micrometers. A material of the vibration layer 128 includes a metal, such as silver (Ag), aluminum (Al), titanium (Ti), steel, or other similar metals. The vibration layer 128 may be formed on surfaces of the third photoresist material PR3 and the support layer 126 by physical vapor deposition, such as evaporation or sputtering.

Referring to FIG. 5L, a counterweight 129 is formed on the vibration layer 128. The counterweight 129 may be formed on the vibration layer 128 by screen printing, spraying, or sputtering. A material of the counterweight 129 includes silver (Ag) or other metal materials.

Referring to FIGS. 5L and 5M, after the manufacturing of the counterweight 129 is completed, the first photoresist material PR1, the second photoresist material PR2, and the third photoresist material PR3 are removed, so as to form a microfluidic chamber 115 including the first microfluidic chamber region 115a and the second microfluidic chamber region 115b in the insulating layer 114, and to form the air gap 125 between the vibration layer 128 and the first electrode 122b. After removing the first photoresist material PR1, the second photoresist material PR2, and the third photoresist material PR3, the vibrotactile component 120 is completed. A weight of the counterweight 129 accounts for a percentage in a range of 5% to 60% of a total weight of the vibrotactile component 120. A thickness of the counterweight 129 is approximately 100 micrometers, and a distance between a center of mass of the counterweight 129 and a center of the vibration layer 128 does not exceed 37.5% of a side length or a diameter of the vibration layer 128, so as to ensure that its resonance frequency may fall within an optimal tactile sensing range of a finger (for example, between 10 Hz and 1000 Hz).

Referring to FIG. 5N, after the manufacturing of the counterweight 129 is completed, the structure in FIG. 5M is flipped, so that the insulating layer 114 is located above the flexible substrate 140. Next, a dielectric fluid 116 is filled into the first microfluidic chamber region 115a and the second microfluidic chamber region 115b in the insulating layer 114, wherein the dielectric fluid 116 includes a first portion 116a contained in the first microfluidic chamber region 115a and a second portion 116b contained in the second microfluidic chamber region 115b. At this stage, an exposed surface of the dielectric fluid 116 may be flush with an interface between the second insulating portion 114b and the top electrode 112b. However, this embodiment is not limited thereto. In embodiments, the exposed surface of the dielectric fluid 116 may be slightly higher than the interface between the second insulating portion 114b and the top electrode 112b. The exposed surface of the dielectric fluid 116 may be flush with a top surface of the top electrode 112b.

Referring to FIG. 5O, after the dielectric fluid 116 is filled, a deformation layer 118 is then attached. After the deformation layer 118 is formed, the deformation component 110 is completed.

Referring to FIGS. 5P and 5Q, after the manufacturing of the deformation component 110 is completed, the manufacturing of the electrostatic friction component 130 is continued on the deformation layer 118. First, an electrode 132 is formed on the deformation layer 118. Next, an electrostatic friction layer 134 is formed on the electrode 132. The electrode 132 and the electrostatic friction layer 134 may be formed by screen printing.

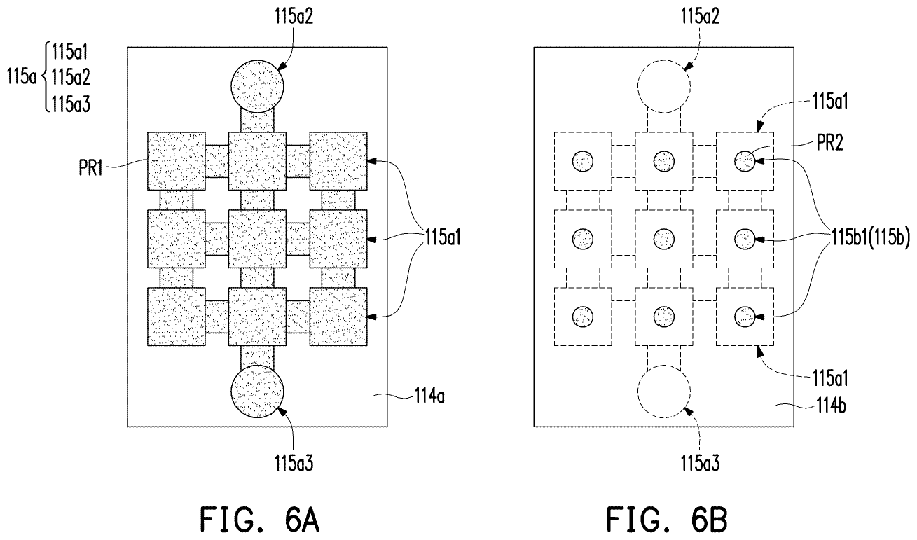

FIGS. 6A and 6B are schematic top views of photoresist materials manufactured by a two-stage screen printing process according to one or more embodiments, wherein FIG. 6A is a top view corresponding to FIG. 5C, and FIG. 6B is a top view corresponding to FIG. 5E.

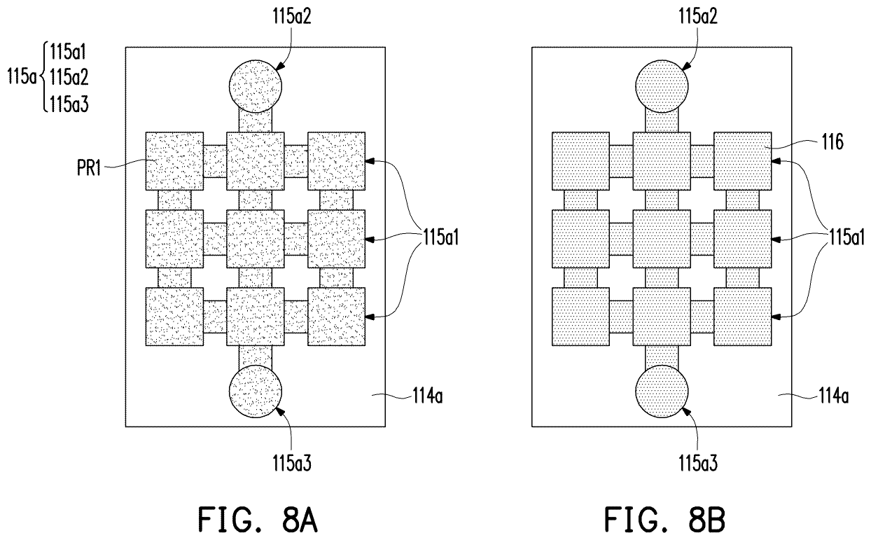

As shown in FIG. 6A, the first microfluidic chamber region 115a formed in the first insulating portion 114a includes a plurality of unit chambers 115a1 interconnected with each other, and includes photoresist removal holes 115a2 and 115a3. In a square region with a side length of 1 centimeter, nine square unit chambers 115a1 interconnected with each other are arranged in a 3×3 array. Photoresist removal holes 115a2 and 115a3 are distributed above and below the 3×3 array, respectively. The photoresist removal holes 115a2 and 115a3 may be used in a subsequent process (i.e., the process in FIG. 5M) to remove the first photoresist material PRI and the second photoresist material PR2. As shown in FIGS. 8A and 8B, the photoresist removal hole 115a2 may serve as a filling inlet for the dielectric fluid 116 in a subsequent process (i.e., the process in FIG. 5N), and the photoresist removal hole 115a3 may serve as a filling outlet for the dielectric fluid 116 in the subsequent process (i.e., the process in FIG. 5N).

As shown in FIG. 6B, the second microfluidic chamber region 115b formed in the second insulating portion 114b includes a plurality of unit chambers 115b1 that are separated from each other. The unit chambers 115b1 overlap the unit chambers 115a1. An area occupied by the unit chambers 115b1 is smaller than an area occupied by the unit chambers 115a1. The unit chambers 115b1 are in communication with the unit chambers 115a1, but the unit chambers 115b1 do not overlap the photoresist removal holes 115a2 and 115a3.

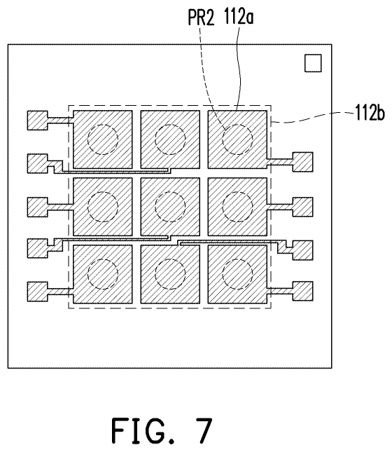

FIG. 7 is a top view schematic diagram of a conductive layer of the deformation component according to an embodiment.

Referring to FIGS. 6A, 6B, and 7, a distribution area of the bottom electrode 112a is larger than a distribution area of the top electrode 112b. The distribution area of the bottom electrode 112a is sufficient to cover all the unit chambers 115a1 that are interconnected with each other, while the distribution area of the top electrode 112b only covers one of the corresponding unit chambers 115a1. Each of the top electrodes 112b is electrically isolated from one another, so that the respective area underneath may be driven individually.

Referring to FIGS. 8A and 8B, the first photoresist material PR1 (illustrated in FIG. 8A) in the unit chambers 115a1, the photoresist removal hole 115a2, and the photoresist removal hole 115a3 is removed through at least one of the photoresist removal holes 115a2 and 115a3. Next, as shown in FIG. 8B, the dielectric fluid 116 is filled into the unit chambers 115a1 through at least one of the photoresist removal holes 115a2 and 115a3.

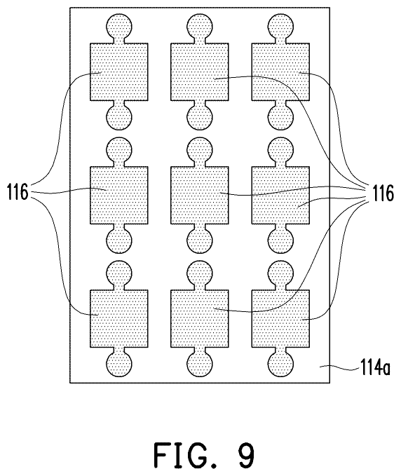

FIG. 9 is a schematic top view schematic diagram after a different dielectric fluid is filled in the insulating layer in an embodiment.

Referring to FIGS. 8B and 9, the process illustrated in FIG. 9 is similar to the process illustrated in FIG. 8B; nevertheless, in FIG. 8B, the plurality of unit chambers 115a1 according to FIG. 9 are not interconnected with each other. The individual unit chambers 115a1 distributed in the first insulating portion 114a may be filled with the same or different dielectric fluids 116 to provide more diverse haptics.

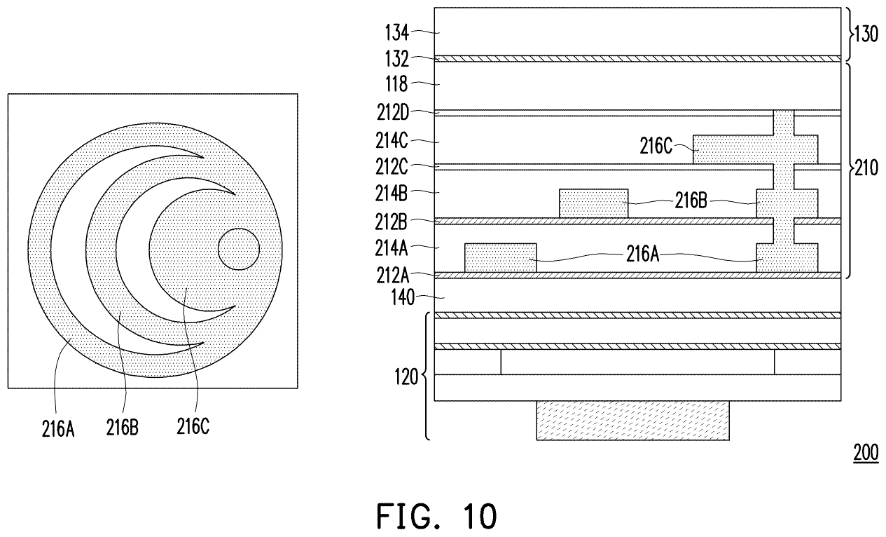

FIG. 10 is a schematic cross-sectional view of a haptic device and a top view schematic diagram of a deformation component according to an embodiment.

Referring to FIG. 10, a haptic device 200 is similar to the haptic device 100 illustrated in FIG. 1A. The main difference between the two is that the haptic device 200 includes a multilayer-structured deformation component 210. The deformation component 210 includes a bottom electrode 212A, an intermediate electrode 212B, an intermediate electrode 212C, a top electrode 212D, an insulating layer 214A, an insulating layer 214B, an insulating layer 214C, a dielectric fluid 216A, a dielectric fluid 216B, and a dielectric fluid 216C. The bottom electrode 212A is disposed on the flexible substrate 140. The insulating layer 214A is disposed on the bottom electrode 212A. The dielectric fluid 216A is distributed in the insulating layer 214A. The intermediate electrode 212B is disposed on the insulating layer 214A and the dielectric fluid 216A. A cross-voltage applied between the bottom electrode 212A and the intermediate electrode 212B causes the dielectric fluid 216A to be compressed. The actuation mechanism is similar to that of the haptic device 100. The insulating layer 214B is disposed on the intermediate electrode 212B. The dielectric fluid 216B is distributed in the insulating layer 214B. The intermediate electrode 212C is disposed on the insulating layer 214B and the dielectric fluid 216B. A cross-voltage applied between the intermediate electrode 212B and the intermediate electrode 212C causes the dielectric fluid 216B to be compressed. The actuation mechanism is similar to that of the haptic device 100. The insulating layer 214C is disposed on the intermediate electrode 212C. The dielectric fluid 216C is distributed in the insulating layer 214C. The top electrode 212D is disposed on the insulating layer 214C and the dielectric fluid 216C. A cross-voltage applied between the intermediate electrode 212C and the top electrode 212D causes the dielectric fluid 216C to be compressed. The actuation mechanism is similar to that of the haptic device 100. The dielectric fluid 216A, the dielectric fluid 216B, and the dielectric fluid 216C distributed in different layers contact each other.

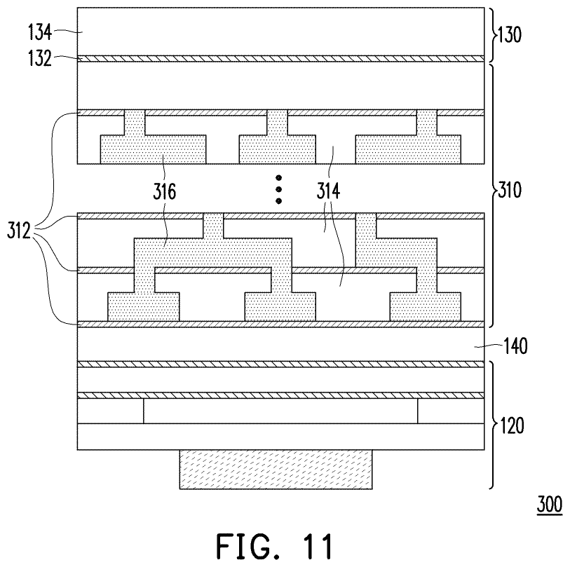

FIG. 11 is a schematic cross-sectional view of a haptic device according to an embodiment.

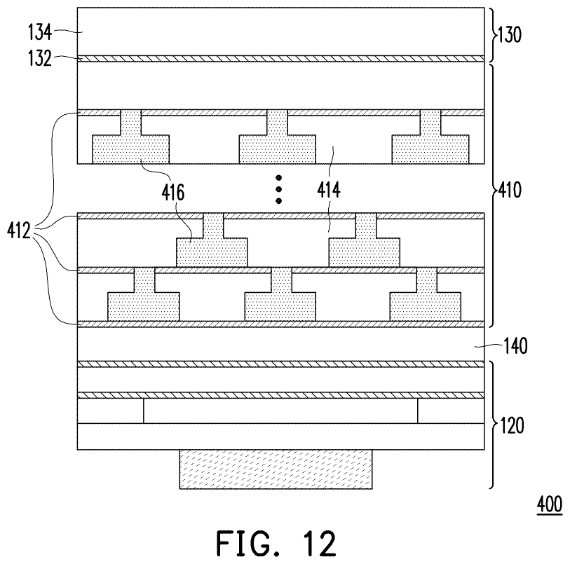

Referring to FIGS. 10 and 11, a haptic device 300 is similar to the haptic device 200. The main difference between the two is that a deformation component 310 in the haptic device 300 includes multiple layers of electrodes 312, multiple layers of insulating layers 314, and multiple layers of dielectric fluid 316, wherein multiple layers of the electrodes 312 and the insulating layers 314 are alternately stacked on the flexible substrate 140, and multiple layers of the dielectric fluid 316 contact each other. FIG. 12 is a schematic cross-sectional view of a haptic device according to an embodiment.

Referring to FIGS. 11 and 12, a haptic device 400 is similar to the haptic device 300. The main difference between the two is that a deformation component 410 in the haptic device 400 includes multiple layers of electrodes 412, multiple layers of insulating layers 414, and multiple layers of dielectric fluid 416, wherein multiple layers of the electrodes 412 and multiple layers of the insulating layers 414 are alternately stacked on the flexible substrate 140, and multiple layers of the dielectric fluid 416 are independent (and isolated) from one another and do not contact each other.

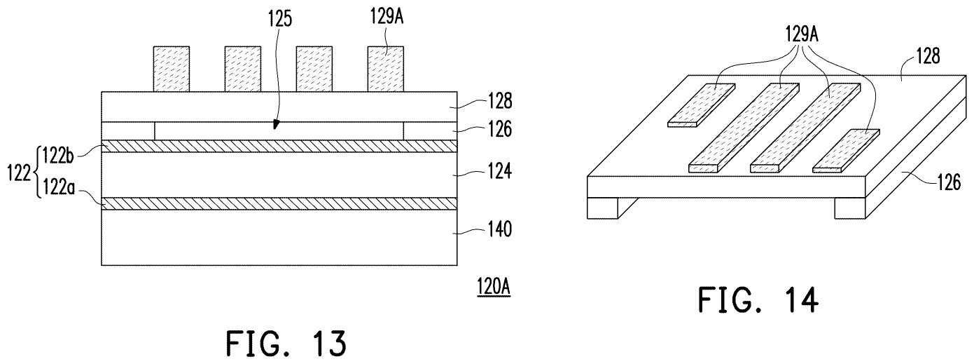

FIG. 13 is a schematic cross-sectional view of a vibrotactile component according to an embodiment. FIG. 14 is a perspective schematic diagram of a counterweight, a vibration layer, and a support layer of the vibrotactile component according to an embodiment.

Referring to FIGS. 13 and 14, a vibrotactile component 120A includes a second electrode pair 122, a flexible piezoelectric layer 124, a support layer 126, a vibration layer 128, and a counterweight 129A. The second electrode pair 122 is disposed on a surface of the flexible substrate 140. The flexible piezoelectric layer 124 is disposed between the second electrode pair 122. The support layer 126 is disposed on the second electrode pair 122 to define an air gap 125. The support layer 126 and the flexible substrate 140 are respectively located on two opposite sides of the second electrode pair 122. The support layer 126 is located above the second electrode pair 122 and the flexible piezoelectric layer 124, and the flexible substrate 140 is located below the second electrode pair 122 and the flexible piezoelectric layer 124. The vibration layer 128 is disposed on the support layer 126, and the vibration layer 128 and the second electrode pair 122 are spaced from each other by the air gap 125. The counterweight 129A is disposed on the vibration layer 128.

The second electrode pair 122 includes a first electrode 122b and a second electrode 122a, wherein the second electrode 122a is located between the flexible piezoelectric layer 124 and the flexible substrate 140, and the first electrode 122b is located between the flexible piezoelectric layer 124 and the support layer 126. As shown in FIGS. 13 and 14, the counterweight 129A may be a counterweight set that includes sub-counterweights that are separated from each other, and the sub-counterweights may respectively have the same or different weights according to the required vibration frequency.

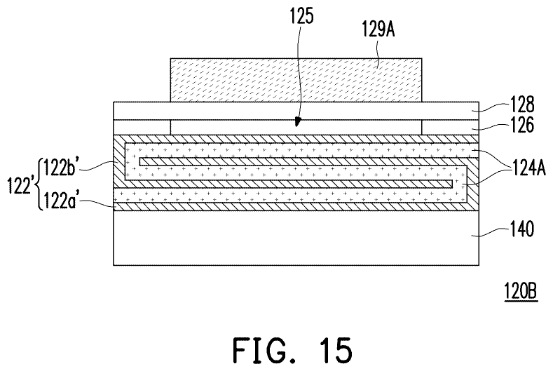

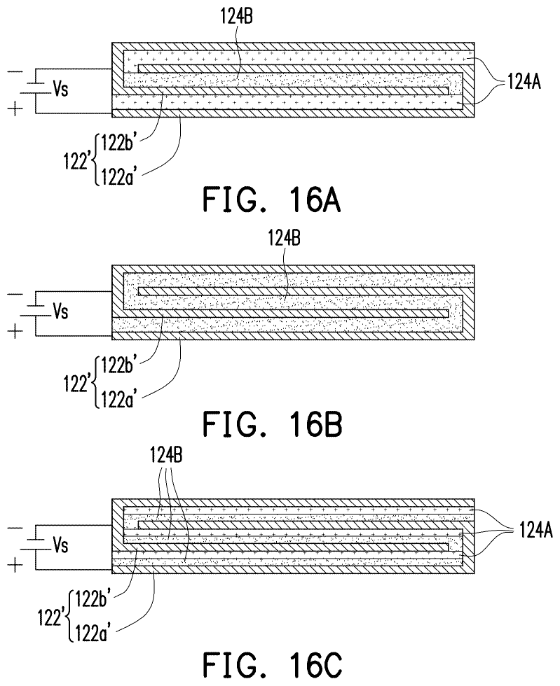

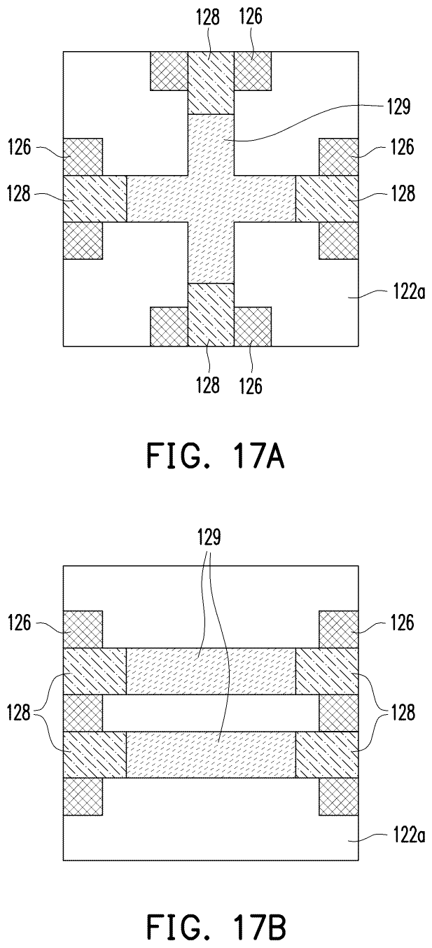

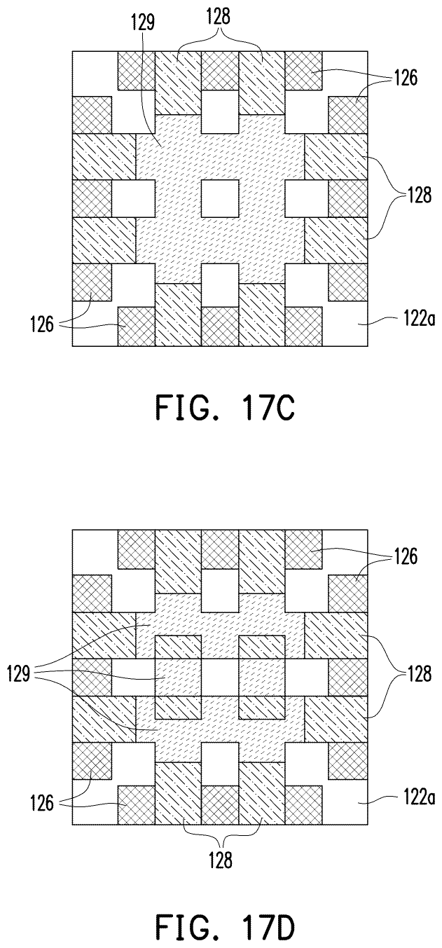

FIG. 15 is a schematic cross-sectional view of a vibrotactile component according to an embodiment.

Referring to FIG. 15, a vibrotactile component 120B includes a second electrode pair 122′, an organic flexible piezoelectric layer 124A, a support layer 126, a vibration layer 128, and a counterweight 129A. The second electrode pair 122′ is disposed on a surface of the flexible substrate 140. The organic flexible piezoelectric layer 124A is disposed between the second electrode pair 122′. The support layer 126 is disposed on the second electrode pair 122′ to define an air gap 125. The support layer 126 and the flexible substrate 140 are respectively located on two opposite sides of the second electrode pair 122′. For example, the support layer 126 is located above the second electrode pair 122′ and the organic flexible piezoelectric layer 124A, and the flexible substrate 140 is located below the second electrode pair 122′ and the organic flexible piezoelectric layer 124A. The vibration layer 128 is disposed on the support layer 126, and the vibration layer 128 and the second electrode pair 122′ are spaced from each other by the air gap 125. The counterweight 129A is disposed on the vibration layer 128.

The second electrode pair 122′ includes an electrode 122a′ and an electrode 122b′. The organic flexible piezoelectric layer 124A is distributed between the electrode 122a′ and the electrode 122b′. The organic flexible piezoelectric layer 124A distributed between the electrode 122a′ and the electrode 122b′ may include multiple layers that overlap each other and are connected to each other.

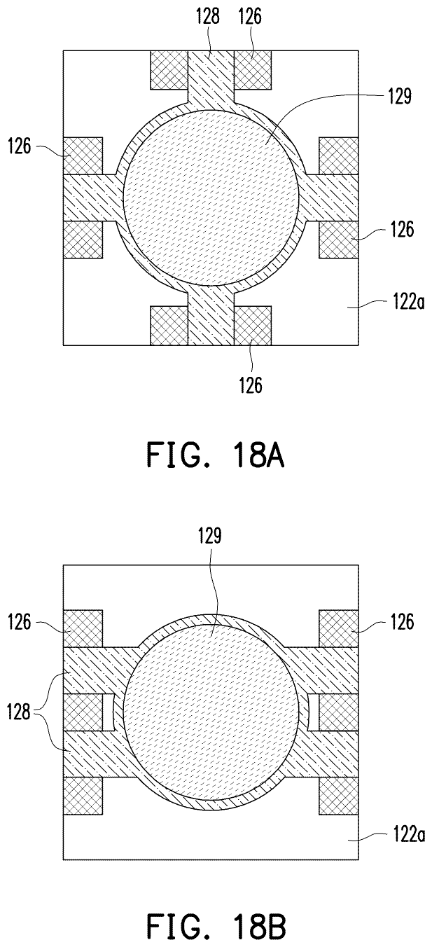

FIGS. 16A to 16C are schematic diagrams of different flexible piezoelectric layer designs of the vibrotactile component according to one or more embodiments.

The flexible piezoelectric layer distributed between the electrode 122a′ and the electrode 122b′ may include alternately stacked one or more organic flexible piezoelectric layers 124A and one or more inorganic flexible piezoelectric layers 124B, as shown in FIGS. 16A and 16B. The flexible piezoelectric layer distributed between the electrode 122a′ and the electrode 122b′ may include only inorganic flexible piezoelectric layers 124B, as shown in FIG. 16C.

FIGS. 17A to 17D, FIGS. 18A to 18D, and FIGS. 19A to 19D are schematic top views of the counterweight 129, the vibration layer 128, and the support layer 126 of the vibrotactile component according to one or more embodiments.

Referring to FIG. 17A, the support layer 126 includes four separated support patterns, and the four separated support patterns are respectively disposed at the four centers of four edges of the electrode 122a. The vibration layer 128 is a cross-shaped structure overlapping the support layer 126, and the counterweight 129 is a cross-shaped structure disposed on the vibration layer 128. As shown in FIG. 17A, in a plan view, the distribution area of the counterweight 129 is smaller than the distribution area of the vibration layer 128, and the distribution range of the counterweight 129 does not exceed the distribution range of the vibration layer 128.

Referring to FIG. 17B, the support layer 126 includes two separated support patterns, and the two separated support patterns are disposed at two opposite edges of the electrode 122a. The vibration layer 128 includes two parallel strip-shaped (or bar-shaped) structures overlapping the support layer 126, and the counterweight 129 (a counterweight set) is composed of two parallel strip-shaped (or bar-shaped) structures disposed on the vibration layer 128. As shown in FIG. 17B, in a plan view, the distribution area of the counterweight 129 is smaller than the distribution area of the vibration layer 128, and the distribution range of the counterweight 129 does not exceed the distribution range of the vibration layer 128.

Referring to FIGS. 17C and 17D, the support layer 126 includes four support patterns, and the four support patterns are respectively disposed at four edges of the electrode 122a. The vibration layer 128 includes a mesh structure overlapping the support layer 126, and the counterweight 129 is a mesh structure disposed on the vibration layer 128. As shown in FIGS. 17C and 17D, in plan views, the distribution area of the counterweight 129 is smaller than the distribution area of the vibration layer 128, and the distribution range of the counterweight 129 does not exceed the distribution range of the vibration layer 128.

Referring to FIGS. 18A to 18D, the structures shown in FIGS. 18A to 18D are similar to the structures shown in FIGS. 17A to 17D, and the differences may include that the vibration layer 128 has a circular structure, and the counterweight 129 also has a circular structure (as shown in FIGS. 18A to 18C) or an annular structure (as shown in FIG. 18D).

Referring to FIGS. 19A to 19D, the structures shown in FIGS. 19A to 19D are similar to the structures shown in FIGS. 18A to 18D, and the differences may include that the electrode 122a is substantially circular rather than substantially rectangular. The counterweight 129, the vibration layer 128, and the support layer 126 are all distributed within the distribution range of the electrode 122a.

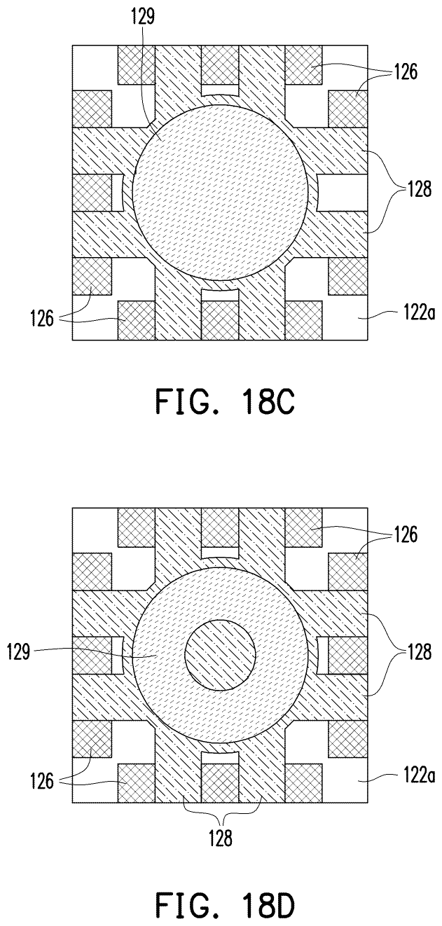

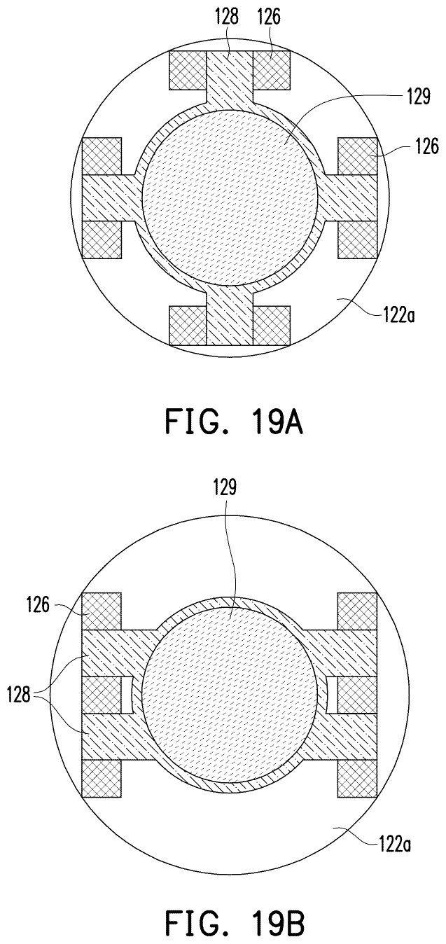

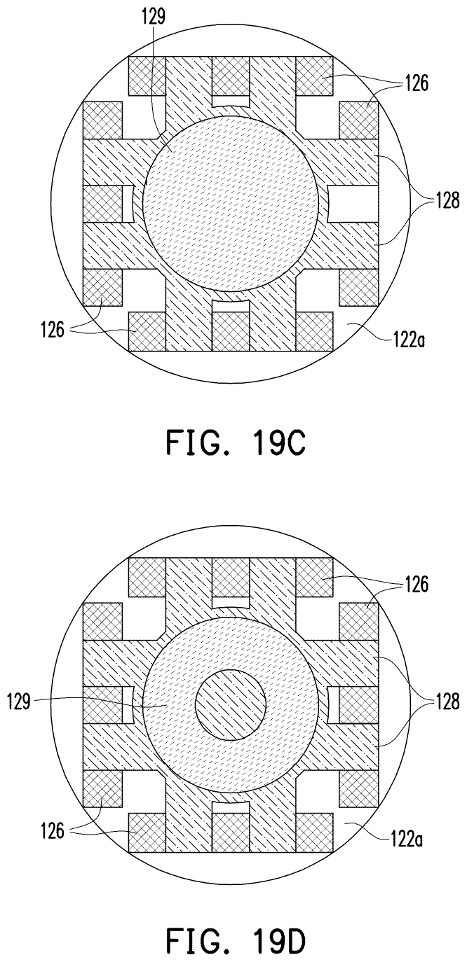

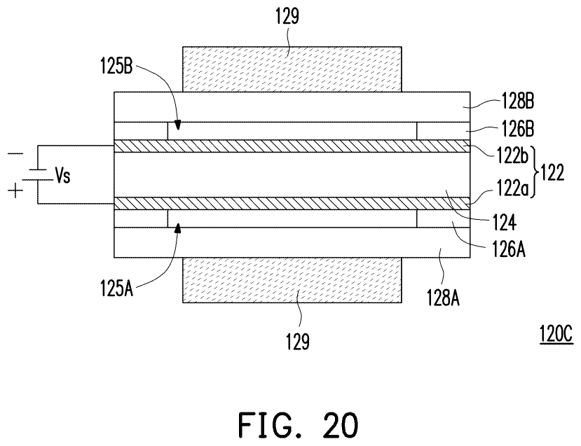

FIG. 20 is a schematic cross-sectional view of a vibrotactile component according to an embodiment.

Referring to FIG. 20, a vibrotactile component 120C includes the second electrode pair 122, the flexible piezoelectric layer 124, a support layer 126A, a support layer 126B, a vibration layer 128A, a vibration layer 128B, and multiple counterweights 129. The second electrode pair 122 includes the second electrode 122a and the first electrode 122b, and the second electrode 122a and the first electrode 122b are respectively disposed on two opposite surfaces of the flexible piezoelectric layer 124. The flexible piezoelectric layer 124 is disposed between the second electrode 122a and the first electrode 122b. The support layer 126A is disposed on a bottom surface of the second electrode 122a to define an air gap 125A, and the support layer 126B is disposed on a top surface of the first electrode 122b to define an air gap 125B. The vibration layer 128A is disposed on the support layer 126A and is separated from the second electrode 122a by the air gap 125A. The vibration layer 128B is disposed on the support layer 126B and is separated from the first electrode 122b by the air gap 125B. The counterweights 129 are disposed on the vibration layer 128A and the vibration layer 128B.

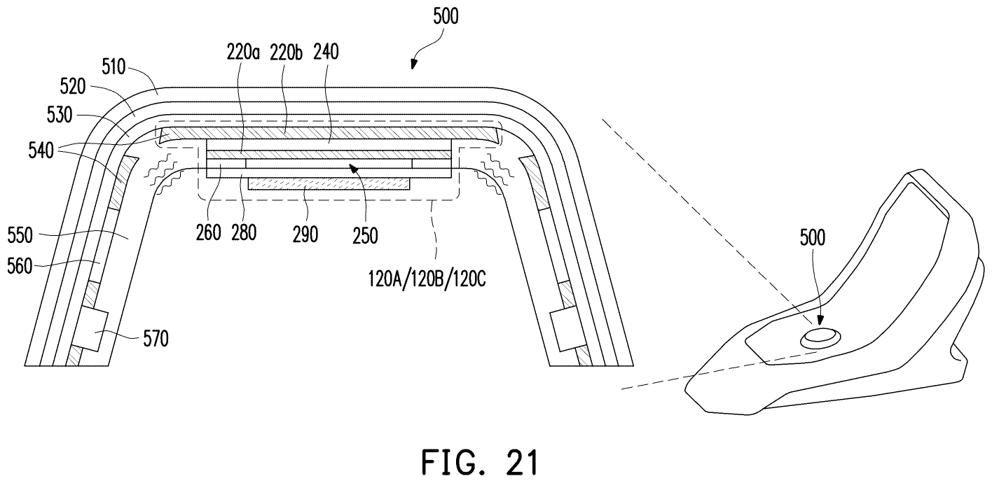

FIG. 21 shows schematic diagrams illustrating a vibrotactile component and a knob 500 including the vibrotactile component according to an embodiment.

Referring to FIG. 21, the vibrotactile component 120A (shown in FIG. 13), the vibrotactile component 120B (shown in FIG. 15), and/or the vibrotactile component 120C (shown in FIG. 20) may be integrated into the knob 500. The knob 500 may be a control knob in a vehicle electronic device. Integrating the vibrotactile component 120A, the vibrotactile component 120B, or the vibrotactile component 120C into the knob 500 may provide proper tactile or vibration feedback, allowing the user to obtain desirable tactile or vibration feedback when using the knob 500.

As shown in FIG. 21, the knob 500 further includes a substrate 510, a pattern layer 520, a planar layer 530, a circuit layer 540, a package layer 550, a touch layer 560, and a photoelectric element 570. The substrate 510 may be regarded as a carrier. The pattern layer 520, the planar layer 530, the circuit layer 540 (i.e., the electrode 220b), the package layer 550, the touch layer 560, and the photoelectric element 570 are disposed on an inner surface of the substrate 510, and the circuit layer 540 plays the role of an electrode in the vibrotactile component 120A, the vibrotactile component 120B, or the vibrotactile component 120C for driving the vibrotactile component 120A, the vibrotactile component 120B, or the vibrotactile component 120C. The vibrotactile component 120A, the vibrotactile component 120B, or the vibrotactile component 120C may be at least partially embedded in the package layer 550.

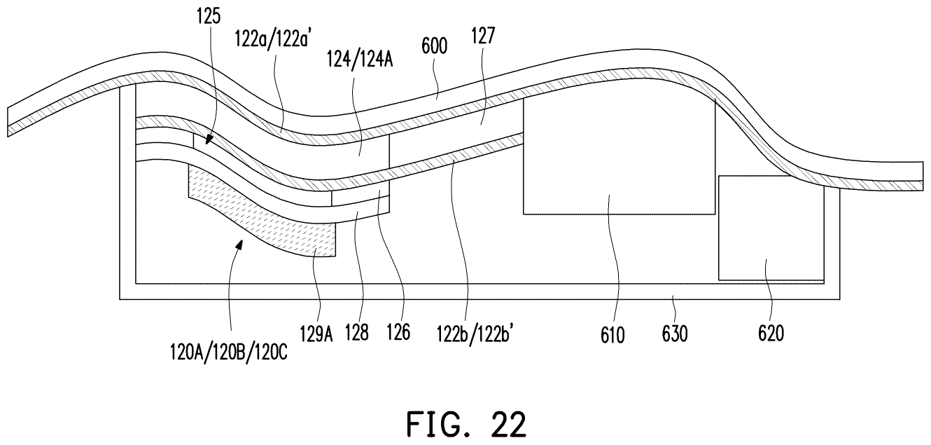

FIG. 22 is a schematic diagram illustrating a piece of fabric 600 including a vibrotactile component according to an embodiment. Referring to FIG. 22, the vibrotactile component 120A (shown in FIG. 13), the vibrotactile component 120B (shown in FIG. 15), and/or the vibrotactile component 120C (shown in FIG. 20) may be integrated into the fabric 600. Integrating the vibrotactile component 120A, the vibrotactile component 120B, or the vibrotactile component 120C into the fabric 600 may provide appropriate tactile or vibration feedback, allowing the user to obtain desirable tactile or vibration feedback when using the fabric 600. As shown in FIG. 22, a control unit 610, a power supply unit 620, and a protective casing 630 may be included beneath the fabric 600, wherein the protective casing 630 not only covers the control unit 610 and the power supply unit 620 but also covers the vibrotactile component 120A, the vibrotactile component 120B, or the vibrotactile component 120C. The fabric 600 and the protective casing 630 may be regarded as a carrier. The power supply unit 620 is electrically connected to the control unit 610 and provides power to the control unit 610, and the control unit 610 is electrically connected to the vibrotactile component 120A, the vibrotactile component 120B, or the vibrotactile component 120C to drive the vibrotactile component 120A, the vibrotactile component 120B, or the vibrotactile component 120C. The vibrotactile component 120A, the vibrotactile component 120B, or the vibrotactile component 120C may further include an insulating layer 127 located between the electrode 122a/122a′ and the electrode 122b/122b′, wherein the insulating layer 127 is adjacent to the flexible piezoelectric layer 124/124A, and the flexible piezoelectric layer 124/124A is separated and insulated from the control unit 610 by the insulating layer 127.

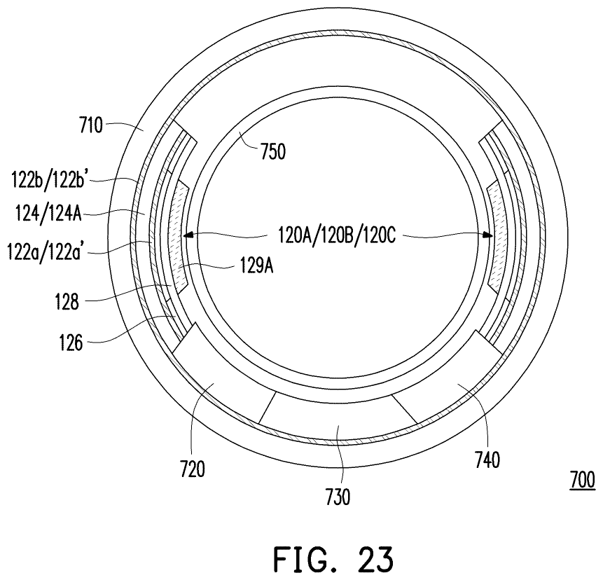

FIG. 23 is a schematic diagram illustrating vibrotactile component a ring-type device (e.g., a ring, bracelet or collar) 700 including a vibrotactile component according to an embodiment.

Referring to FIG. 23, the vibrotactile component 120A (shown in FIG. 13), the vibrotactile component 120B (shown in FIG. 15), and/or the vibrotactile component 120C (shown in FIG. 20) may be integrated into the ring-type device 700 (e.g., a ring, bracelet or collar). Integrating the vibrotactile component 120A, the vibrotactile component 120B, or the vibrotactile component 120C into the ring-type device 700 (e.g., a ring, bracelet, collar, etc.) may provide appropriate tactile or vibration feedback, allowing the user to obtain desirable tactile or vibration feedback when using the ring-type device (e.g., a ring, bracelet, collar, etc.) 700.

As shown in FIG. 23, the ring-type device 700 further includes a ring-shaped carrier 710, a power supply unit 720, an optical heart rate sensor 730, a control unit 740, and a packaging layer 750. The ring-shaped carrier 710 may be regarded as a carrier. The power supply unit 720, the optical heart rate sensor 730, the control unit 740, and the packaging layer 750 are all disposed on an inner surface of the ring-shaped carrier 710. The power supply unit 720 provides power to the control unit 740, and the control unit 740 is electrically connected to the optical heart rate sensor 730, the vibrotactile component 120A, the vibrotactile component 120B, or the vibrotactile component 120C to drive the optical heart rate sensor 730, the vibrotactile component 120A, the vibrotactile component 120B, or the vibrotactile component 120C. The packaging layer 750 covers the power supply unit 720, the optical heart rate sensor 730, the control unit 740, and the vibrotactile component 120A, the vibrotactile component 120B, or the vibrotactile component 120C.

In some embodiments, the optical heart rate sensor 730 may be omitted. The ring-type device 700 may not include the optical heart rate sensor 730. The number(s) of the vibrotactile component 120A, the vibrotactile component 120B, and/or the vibrotactile component 120C may be appropriately changed according to design requirements.

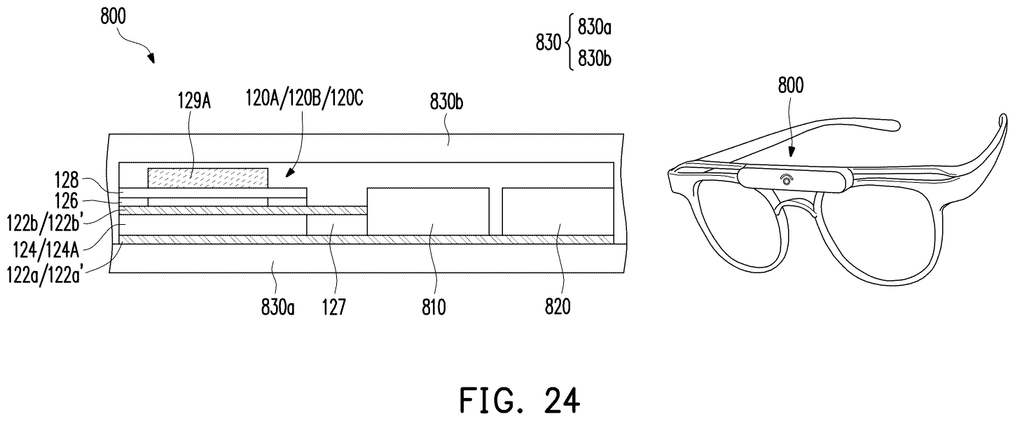

FIG. 24 shows schematic diagram illustrating a vibrotactile component and an eyeglass frame 800 including the vibrotactile component according to an embodiment. As shown in FIG. 24, the vibrotactile component 120A (illustrated in FIG. 13), the vibrotactile component 120B (illustrated in FIG. 15), and/or the vibrotactile component 120C (illustrated in FIG. 20) may be integrated into the eyeglass frame 800 (of smart glasses). Integrating the vibrotactile component 120A, the vibrotactile component 120B, and/or the vibrotactile component 120C into the eyeglass frame 800 may provide suitable haptic or vibration feedback, allowing a user to obtain desirable haptic or vibration feedback through the eyeglass frame 800. As shown in FIG. 24, the eyeglass frame 800 may include a control unit 810, a power supply unit 820, and a protective casing 830. The protective casing 830 may be regarded as a carrier. The power supply unit 820 provides power to the control unit 810, and the control unit 810 is electrically connected to the vibrotactile component 120A, the vibrotactile component 120B, or the vibrotactile component 120C to drive the vibrotactile component 120A, the vibrotactile component 120B, or the vibrotactile component 120C. The protective casing 830 includes a carrier substrate 830a and a protective cover 830b that are connected to each other. The vibrotactile component 120A, the vibrotactile component 120B, or the vibrotactile component 120C may further include an insulating layer 127 located between the electrode 122a/122a′ and the electrode 122b/122b′, wherein the insulating layer 127 is adjacent to the flexible piezoelectric layer 124/124A, and the flexible piezoelectric layer 124/124A is separated from the control unit 810 by the insulating layer 127.

In embodiments, integrating a thin-film-type deformation component into a haptic element may advantageously enable the haptic element to have desirable flexibility. Integrating a thin-film-type deformation component, a vibrotactile component, and/or an electrofriction component into a haptic element may advantageously enable the haptic element to be lighter, more comfortable, and capable of providing more diverse haptics.

Although several embodiments have been described, practical embodiments are not limited to the described embodiments. Various modifications to the described embodiments may be made without departing from the scope of the attached claims.

What is claimed is:

1. A haptic device comprising:
a first electrode;
a second electrode;
a piezoelectric layer disposed between the first electrode and the second electrode;
a support layer disposed on the first electrode, wherein a gap is positioned between two portions of the support layer;
a vibration layer disposed on the support layer and spaced from the first electrode by the support layer and the gap;
a counterweight disposed on the vibration layer, wherein the vibration layer is disposed between the gap and the counterweight;
an electrostatic friction component; and
a deformation component disposed between the second electrode and the electrostatic friction component.

2. The haptic device according to claim 1, further comprising: a substrate disposed between the deformation component and the second electrode.

3. The haptic device according to claim 2, wherein the deformation component comprises:
a third electrode;
a fourth electrode directly contacting a first surface of the substrate;
an insulating layer disposed between the third electrode and the fourth electrode and including a chamber;
a dielectric fluid directly contacting each of the third electrode and the fourth electrode and at least partially located in the chamber; and
a deformation layer directly contacting the third electrode and the dielectric fluid.

4. The haptic device according to claim 3, wherein the second electrode directly contacts a second surface of the substrate, and the second surface of the substrate is opposite the first surface of the substrate.

5. The haptic device according to claim 3, wherein the electrostatic friction component comprises:
an electrostatic friction layer; and
a fifth electrode disposed between the deformation layer and the electrostatic friction layer.

6. The haptic device according to claim 3, wherein the insulating layer comprises:
a first insulating portion directly contacting the third electrode, wherein a first portion of the dielectric fluid is disposed between two opposite sections of the first insulating portion and directly contacts each of the two opposite sections of the first insulating portion; and
a second insulating portion directly contacting the fourth electrode and located between the first insulating portion and the fourth electrode, wherein a second portion of the dielectric fluid is disposed between two opposite parts of the second insulating portion, directly contacts each of the two opposite parts of the second insulating portion, and is wider than the first portion of the dielectric fluid.

7. A vibrotactile component comprising:
a first electrode;
a second electrode;
a piezoelectric layer disposed between the first electrode and the second electrode;
a support layer disposed on the first electrode, wherein a gap is positioned between a first portion of the support layer and a second portion of the support layer;
a vibration layer disposed on the support layer and spaced from the first electrode by the support layer and the gap; and
a counterweight set disposed on the vibration layer, wherein the vibration layer is disposed between the gap and the counterweight sets.

8. The vibrotactile component according to claim 7, wherein the first electrode is disposed between the piezoelectric layer and the support layer.

9. The vibrotactile component according to claim 8, further comprising a substrate, wherein the second electrode is located between the substrate and the piezoelectric layer.

10. The vibrotactile component according to claim 7, wherein the counterweight set comprises a first counterweight and a second counterweight that are spaced from each other.

11. The vibrotactile component according to claim 7, wherein the piezoelectric layer comprises at least one of an organic piezoelectric layer and an inorganic piezoelectric layer.

12. The vibrotactile component according to claim 7, wherein the piezoelectric layer comprises organic piezoelectric layers and inorganic piezoelectric layers that are alternately stacked.

13. The vibrotactile component according to claim 7, wherein a ratio of a maximum width of the first portion of the support layer to a maximum width of the flexible piezoelectric layer is in a range of 1/10 to ½.

14. The vibrotactile component according to claim 7, wherein a Young's module of the vibration layer is in a range of 70 GPa to 210 GPa, and a thickness of the vibration layer is greater than or equal to 3 micrometers.

15. The vibrotactile component according to claim 7, wherein a weight of the counterweight accounts for a percentage in a range of 5% to 60% of a weight of the vibrotactile component.

16. The vibrotactile component according to claim 7, wherein a distance between a center of mass of the counterweight and a center of the vibrotactile component does not exceed 37.5% of a side length or a diameter of the vibration layer.

17. A haptic device comprising:
a carrier;
a vibrotactile component disposed on the carrier, wherein the vibrotactile component comprises:
a first electrode;
a second electrode;
a flexible piezoelectric layer disposed between the first electrode and the second electrode;
a support layer disposed on the first electrode, wherein a gap is positioned between a first portion of the support layer and a second portion of the support layer;
a vibration layer disposed on the support layer and spaced from the first electrode by the support layer and the gap;
a counterweight disposed on the vibration layer, wherein the vibration layer is disposed between the gap and the counterweight; and
a control unit disposed on the carrier and electrically connected to the vibrotactile component.

18. The haptic device according to claim 17, further comprising: a power supply unit disposed on the carrier and electrically connected to the control unit.

19. The haptic device according to claim 17, wherein the carrier comprises a knob, a fabric, a ring, a bracelet, a collar, or an eyeglass frame.

20. The haptic device according to claim 17, wherein a weight of the counterweight accounts for a percentage in a range of 5% to 60% of a weight of the vibrotactile component.
